(19) United States
(12) Patent Application Publication
(10) Pub. No.: US 2008/0017108 A1
(43) Pub. Date: Jan. 24, 2008

(54) Gas combustion apparatus

(76) Inventors: Michael Roger Czerniak, Partridge Green (GB); Darren Mennie, Portishead (GB)

Correspondence Address: Edwards Vacuum, Inc., 55 MADISON AVENUE, Suite 400, MORRISTOWN, NJ, 07960, US

(21) Appl. No.: 11/824,067

(22) Filed: Jun. 29, 2007

(30) Foreign Application Priority Data
Jun. 30, 2006 (GB) 0613044.7

(51) Int. Cl. C23C 16/00; F23C 7/00

(52) U.S. Cl. 118/715; 431/354; 431/8

(57) ABSTRACT

A method of combusting a gas comprises the steps of conveying the gas to a combustion nozzle connected to a combustion chamber, and supplying to the chamber gas for forming a pilot flame around the combustion nozzle. To form the pilot flame, hydrogen is supplied to the chamber through a first plurality of apertures extending about the combustion nozzle, and an oxidant is supplied to the chamber, separately from the hydrogen, through a second plurality of apertures extending about the combustion nozzle.

### FIELD OF THE INVENTION

The present invention relates to apparatus for, and a method of, combusting gas, and which may be used, but not exclusively, for the combustion of a flammable gas.

### BACKGROUND OF THE INVENTION

A primary step in the fabrication of semiconductor devices is the formation of a thin film on a semiconductor substrate by chemical reaction of vapour precursors. One known technique for depositing a thin film on a substrate is chemical vapour deposition (CVD). In this technique, process gases are supplied to a process chamber housing where the substrate and process gases react to form a thin film over the surface of the substrate.

An example of a material commonly deposited on to a substrate is gallium nitride (GaN). GaN, and related material alloys (such as InGaN, AlGaN and InGaAlN) are compound semiconductors used for the manufacture of green, blue and white light emitting devices (such as LEDs and laser diodes) and power devices (such as HBTs and HEMTs). These compound semiconductors are usually formed using a form of CVD usually known as MOCVD (metal organic chemical vapour deposition). In overview, this process involves reacting together volatile organometallic sources of the group III metals Ga, In and/or Al, such as trimethyl gallium (TMG), trimethyl indium (TMI) and trimethyl aluminium (TMA), with ammonia at elevated temperatures to form thin films of material on wafers of a suitable substrate material (such as Si, SiC, sapphire or AlN). Hydrogen gas is generally also present, providing a carrier gas for the organometallic precursor and the other process gases.

Following the deposition process conducted within the process chamber, there is typically a residual amount of the gases supplied to the process chamber contained in the gas exhaust from the process chamber. Process gases such as ammonia and hydrogen are highly dangerous if exhausted to the atmosphere, and so in view of this, before the exhaust gas is vented to the atmosphere, abatement apparatus is often provided to treat the exhaust gas to convert the more hazardous components of the exhaust gas into species that can be readily removed from the exhaust gas, for example by conventional scrubbing, and/or can be safely exhausted to the atmosphere.

A mixture of ammonia and hydrogen is inherently flammable, and so may be conveniently treated by controlled oxidation in a combustion chamber. The combustion chamber has a combustion nozzle for receiving the exhaust gas to be treated. The combustion nozzle is surrounded by a plurality of small diameter nozzles which receive a gas mixture of fuel and air to form a pilot flame within the combustion chamber. The purpose of the pilot flame is to provide a reliable source of ignition for the exhaust gas. The gas mixture is typically a mixture of methane and air, with a ratio of methane to air of around 1:14 to 1:16, which is supplied to a plenum chamber surrounding the combustion nozzle and from which the gas mixture is supplied to these smaller nozzles.

A separate supply of methane is thus required to produce the gas mixture. In view of the presence of a source of hydrogen for use in the MOCVD process, it is desirable to substitute hydrogen for the methane in the gas mixture. However, simply replacing the methane with hydrogen poses a significant risk, as the heat of combustion of the exhaust gas within the chamber could raise the temperature of the plenum chamber to a temperature above the auto-ignition temperature of the mixture of hydrogen and air. This may result in combustion occurring within the plenum chamber, with the risk of flame fronts travelling along supply pipes. Whilst a fuel-only gas may be used to generate the pilot flames, and thereby remove the risk of auto-ignition, pilot flames generated from fuel only tend to be prone to blowing out with varying flow rates of exhaust gas into the combustion chamber.

### BRIEF SUMMARY OF THE INVENTION

In a first aspect, the present invention provides a method of combusting a flammable gas, the method comprising the steps of conveying the gas to a combustion nozzle connected to a combustion chamber, and supplying to the chamber gas for forming a pilot flame around the combustion nozzle, characterised in that hydrogen and an oxidant are injected separately into the chamber to form the pilot flame.

In a second aspect the present invention provides a method of combusting a gas, the method comprising the steps of conveying the gas to a combustion nozzle connected to a combustion chamber, and supplying to the chamber gas for forming a pilot flame around the combustion nozzle, characterised in that, to form the pilot flame, hydrogen is supplied to the chamber through a first plurality of apertures extending about the combustion nozzle and an oxidant is supplied to the chamber, separately from the hydrogen, through a second plurality of apertures extending about the combustion nozzle.

In a third aspect, the present invention provides apparatus for combusting gas, the apparatus comprising a combustion chamber, a combustion nozzle through which the gas to be combusted enters the combustion chamber, and means for supplying to the chamber gas for forming a pilot flame around the combustion nozzle, characterised in that the gas supply means comprises a first plurality of apertures extending about the combustion nozzle, means for supplying hydrogen to the first plurality of apertures, a second plurality of apertures extending about the combustion nozzle, and means for supplying an oxidant to the second plurality of apertures.

The present invention also provides chemical vapour deposition apparatus comprising a process chamber, a hydrogen supply for supplying hydrogen to the process chamber, an ammonia supply for supplying ammonia to the process chamber, and apparatus as aforementioned for treating gas exhausted from the process chamber.

Features described above in relation to method aspects of the invention are equally applicable to apparatus aspects of the invention, and vice versa.

### BRIEF DESCRIPTION OF THE DRAWINGS

Preferred features of the present invention will now be described with reference to the accompanying drawing, in which

FIG. 1 illustrates a process chamber connected to a combustion apparatus;

FIG. 2 illustrates a cross-sectional view of part of the combustion apparatus of FIG. 1; and

FIG. 3 illustrates the arrangement of apertures around a combustion nozzle of FIG. 2 for supplying gas for forming a pilot flame within the combustion chamber.

### DETAILED DESCRIPTION OF THE INVENTION

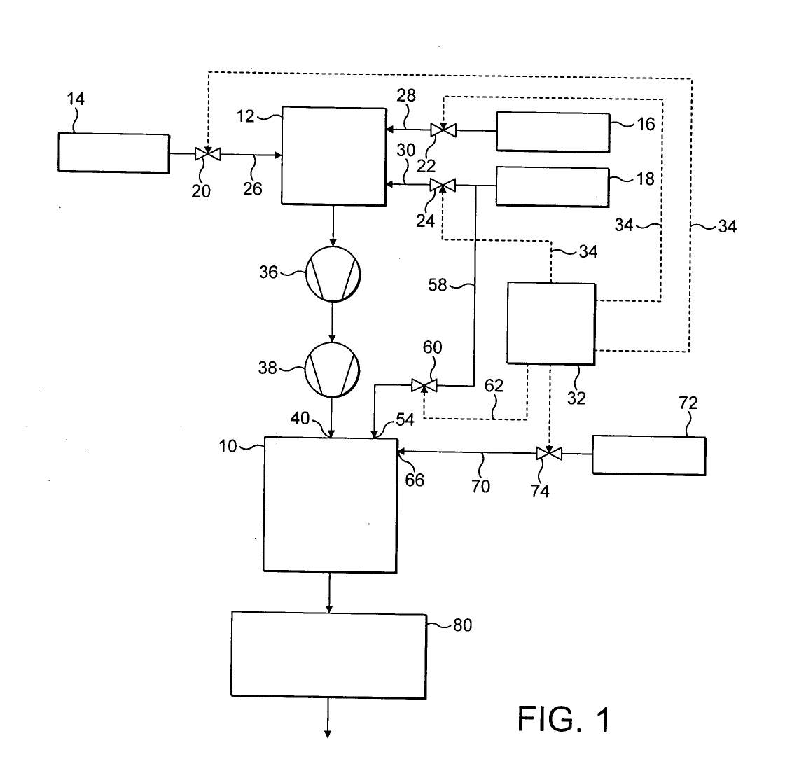

With reference first to FIG. 1, combustion apparatus 10 is provided for treating gases exhausting from a process chamber 12 for processing, for example, semiconductor devices, flat panel display devices or solar panel devices. The chamber 12 receives various process gases for use in performing the processing within the chamber. In this example, MOCVD (metal organic chemical vapour deposition) of a layer of material such as GaN is performed within the process chamber 12. Gases comprising organometallic sources of the group III metals Ga, In and/or Al, such as trimethyl gallium (TMG), trimethyl indium (TMI) and trimethyl aluminium (TMA), ammonia and hydrogen are conveyed to the process chamber 12 from respective sources 14, 16, 18 thereof at elevated temperatures to form thin films of material on wafers of a suitable substrate material (such as Si, SiC, sapphire or AlN).

The supply of the process gases to the process chamber 12 is controlled by the opening and closing of gas supply valves 20, 22, 24 located in gas supply lines 26, 28, 30 respectively. The operation of the gas supply valves is controlled by a supply valve controller 32 which issues control signals 34 to the gas supply valves to open and close the valves according to a predetermined gas delivery sequence.

An exhaust gas is drawn from the outlet of the process chamber 12 by a pumping system. As illustrated in FIG. 1, the pumping system may comprise a secondary pump 36, typically in the form of a turbomolecular pump, for drawing the exhaust gas from the process chamber. The turbomolecular pump 36 can generate a vacuum of at least 10⁻³ mbar in the process chamber 12. The gas is typically exhausted from the turbomolecular pump 36 at a pressure of around 1 mbar. In view of this, the pumping system also comprises a primary, or backing pump 38 for receiving the gas exhaust from the turbomolecular pump 36 and raising the pressure of the gas to a pressure around atmospheric pressure.

During the processing within the chamber, only a portion of the process gases will be consumed, and so the exhaust gas will contain a mixture of the process gases supplied to the chamber, and by-products from the processing within the chamber. The exhaust gases from a GaN MOCVD process, for example, may thus comprise hydrogen and ammonia, and so may be inherently flammable. These gases may be conveniently abated by conveying the gas exhausted from the pumping system is conveyed to the inlet 40 of the combustion apparatus 10, within which the gas is controllably oxidised.

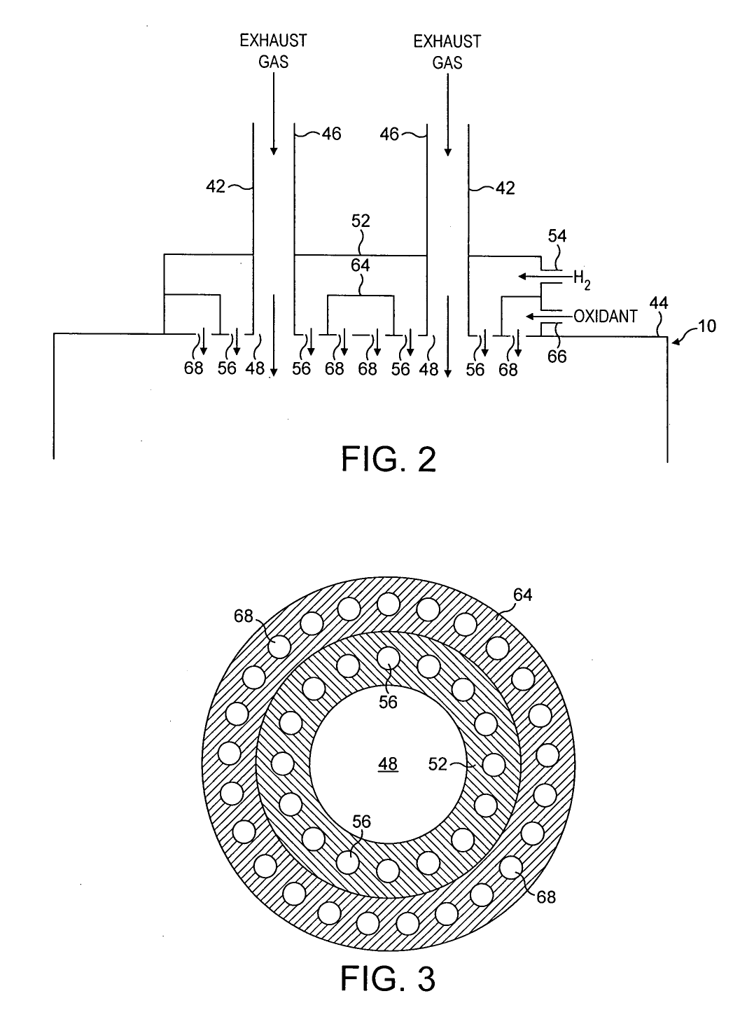

With reference to FIG. 2, the inlet 40 comprises at least one combustion nozzle 42 connected to a combustion chamber 44 of the combustion apparatus 10. Each combustion nozzle 42 has an inlet 46 for receiving the exhaust gas, and an outlet 48 from which the exhaust gas enters the combustion chamber 44. Whilst FIG. 2 illustrates two combustion nozzles 42 for receiving the exhaust gas, the inlet may comprise any suitable number, for example four, six or more, combustion nozzles 42 for receiving the exhaust gas. In the preferred embodiments, the inlet comprises four combustion nozzles 42.

Gas for forming pilot flames around the combustion nozzles is supplied to the combustion chamber 44. The purpose of the pilot flames is to provide a reliable source of ignition for the exhaust gas entering the combustion chamber 44. The gas for forming the pilot flames comprises hydrogen and an oxidant, such as oxygen which may be conveyed to the combustion chamber 44 in an air stream. As described in more detail below, the hydrogen and the oxidant are supplied separately to the combustion chamber 44.

Each combustion nozzle 42 is mounted in a first annular plenum chamber 52 having an inlet 54 for receiving hydrogen for forming the pilot flames, and a plurality of outlets 56 in the form of apertures from which hydrogen enters the combustion chamber 44. As illustrated in FIG. 3, the outlet 48 from each combustion nozzles 42 is surrounded by a plurality of outlets 56 from the first plenum chamber 52.

The source 18 of hydrogen for the process being conducted within the process chamber 12 may conveniently provide a source of hydrogen for forming the pilot flames. As illustrated in FIG. 1, a hydrogen supply line 58 may be connected between the hydrogen source 18 and the inlet 54 for the supply of hydrogen to the combustion chamber 44. A valve 60 may be located in the hydrogen supply line 58 to control the supply of hydrogen to the combustion chamber 44 in response to signals 62 issued by the controller 32. Alternatively, a separate combustion apparatus controller may control the opening and closing of the valve 60.

The first plurality of apertures is preferably concentric with the second plurality of apertures. Hydrogen is preferably supplied to the first plurality of apertures from a first plenum chamber extending about the combustion nozzle, and the oxidant is preferably supplied to the second plurality of apertures from a second plenum chamber extending about the combustion nozzle.

Returning to FIG. 2, the first plenum chamber 52 is located above a second annular plenum chamber 64 having an inlet 66 for receiving the oxidant for forming pilot flames within the combustion chamber 36. The second plenum chamber 64 is shaped such that the combustion nozzles 42 and part of the first plenum chamber are surrounded by the second plenum chamber 64. The second plenum chamber 64 comprises a plurality of outlets 66 in the form of apertures through which the oxidant enters the combustion chamber 44 adjacent the hydrogen to combine with the hydrogen to form the pilot flames. As illustrated in FIG. 3, the outlet 48 from each combustion nozzle 42 is also surrounded by a plurality of outlets 68 from the second plenum chamber 64, which are substantially concentric with and surrounded a plurality of outlets 56 from the first plenum chamber 52.

As illustrated in FIG. 1, an oxidant supply line 70 may be connected between the oxidant source 72 and the inlet 66 for the supply of oxidant to the combustion chamber 44. A valve 74 may be located in the oxidant supply line 70 to control the supply of oxidant to the combustion chamber 44 in response to signals issued by the controller 32. Alternatively, the combustion apparatus controller may control the opening and closing of the valve 74.

The conventional supply of a mixture of a fuel and oxidant into the combustion chamber to form the pilot flame is thus replaced by the separate supplies of hydrogen and an oxidant, such as oxygen, into the combustion chamber to form the pilot flame. The supply of the oxidant provides stability to the pilot flame, in that there is a controllable air supply independent from the gas to be combusted, over a range of flow rates of gas into the combustion chamber, whilst the separate supply of hydrogen and oxygen reduces the risk of the gas supply pipes catching fire due to the heating of the gases during gas combustion.

The hydrogen is preferably injected into the chamber through a first plurality of apertures extending about the combustion nozzle, and the oxidant is preferably injected into the chamber through a second plurality of apertures extending about the combustion nozzle.

The by-products from the combustion of the exhaust gas within the combustion chamber 36 may be conveyed to a wet scrubber, solid reaction media, or other secondary abatement device 80, as illustrated in FIG. 1. After passing through the abatement device 80, the exhaust gas may be safely vented to the atmosphere.

Whilst described above in relation to the treatment of a gas exhausted from an MOCVD apparatus, the combustion apparatus 10 is suitable for use in the treatment of any flammable gas.

While the foregoing description and drawings represent the preferred embodiments of the present invention, it will be apparent to those skilled in the art that various changes and modifications may be made therein without departing from the true spirit and scope of the present invention.

I/we claim:

1. A method of combusting a flammable gas, the method comprising the steps of:
conveying the gas to a combustion nozzle connected to a combustion chamber; and
supplying to the chamber gas for forming a pilot flame around the combustion nozzle,
characterised in that hydrogen and an oxidant are injected separately into the chamber to form the pilot flame.

2. A method according to claim 1, wherein the hydrogen is injected into the chamber through a first plurality of apertures extending about the combustion nozzle and the oxidant is injected into the chamber through a second plurality of apertures extending about the combustion nozzle.

3. A method of combusting a gas, the method comprising the steps of:
conveying the gas to a combustion nozzle connected to a combustion chamber; and
supplying to the chamber gas for forming a pilot flame around the combustion nozzle,
characterised in that, to form the pilot flame, hydrogen is supplied to the chamber through a first plurality of apertures extending about the combustion nozzle and an oxidant is supplied to the chamber, separately from the hydrogen, through a second plurality of apertures extending about the combustion nozzle.

4. A method according to claim 3, wherein the first plurality of apertures is concentric with the second plurality of apertures.

5. A method according to claim 3, wherein the hydrogen is supplied to the first plurality of apertures from a first plenum chamber extending about the combustion nozzle, and the oxidant is supplied to the second plurality of apertures from a second plenum chamber extending about the combustion nozzle.

6. A method according to claim 5, wherein the oxidant comprises oxygen.

7. Apparatus for combusting gas, the apparatus comprising:
a combustion chamber;
a combustion nozzle through which the gas to be combusted enters the combustion chamber; and
a gas supply means comprising: a first plurality of apertures extending about the combustion nozzle; a hydrogen supply for supplying hydrogen gas to the first plurality of apertures; a second plurality of apertures extending about the combustion nozzle; and an oxidant supply for supplying an oxidant to the second plurality of apertures,
wherein the gas supply means supplies gas to the chamber gas for forming a pilot flame around the combustion nozzle.

8. Apparatus according to claim 7, wherein the first plurality of apertures is concentric with the second plurality of apertures.

9. Apparatus according to claim 7, wherein the hydrogen supply comprises a first plenum chamber extending about the combustion nozzle, and the oxidant supply comprises a second plenum chamber extending about the combustion nozzle.

10. Chemical vapour deposition apparatus comprising:
a process chamber;
a hydrogen supply for supplying hydrogen to the process chamber;
an ammonia supply for supplying ammonia to the process chamber; and
an apparatus for treating gas exhausted from the process chamber comprising:
a combustion chamber;
a combustion nozzle through which the gas to be combusted enters the combustion chamber; and
a gas supply means comprising: a first plurality of apertures extending about the combustion nozzle; a hydrogen supply for supplying hydrogen gas to the first plurality of apertures; a second plurality of apertures extending about the combustion nozzle; and an oxidant supply for supplying an oxidant to the second plurality of apertures,
wherein the gas supply means supplies gas to the combustion chamber gas for forming a pilot flame around the combustion nozzle.
